(19) United States
(12) Patent Application Publication
(10) Pub. No.: US 2014/0191328 A1
(43) Pub. Date: Jul. 10, 2014

(54) SEMICONDUCTOR MEMORY DEVICE

(71) Applicant: FUJITSU SEMICONDUCTOR LIMITED, Yokohama-shi (JP)

(72) Inventors: Tomoya TSURUTA, Koganei (JP); Ryo Tanabe, Kawasaki (JP)

(73) Assignee: FUJITSU SEMICONDUCTOR LIMITED, Yokohama-shi (JP)

(21) Appl. No.: 14/133,263

(22) Filed: Dec. 18, 2013

(30) Foreign Application Priority Data
Jan. 10, 2013 (JP) 2013-002926

(51) Int. Cl. H01L 27/092; H01L 27/105

(52) U.S. Cl. CPC H01L 27/0928; H01L 27/1052
USPC 257/371

(57) ABSTRACT

A semiconductor memory device has a memory cell array having memory cells, each including first and second conduction type transistors, a peripheral circuit having the first and second conduction type transistors, a first conduction type memory cell array well region within the memory cell array region, a second conduction type memory cell array well region within the first conduction type memory cell array well region, a first conduction type peripheral circuit well region within the peripheral circuit region, a second conduction type peripheral circuit well region within the first conduction type peripheral circuit well region, and a second conduction type isolation region between the first conduction type memory cell array well region and the first conduction type peripheral circuit well region. At least a portion of first conduction type transistors of first conduction type transistors of the peripheral circuit is formed in the second conduction type isolation region.

### CROSS-REFERENCE TO RELATED APPLICATION

This application is based upon and claims the benefit of priority of the prior Japanese Patent Application No. 2013-002926, filed on Jan. 10, 2013, the entire contents of which are incorporated herein by reference.

### FIELD

The present invention relates to a semiconductor memory device.

### BACKGROUND

Semiconductor memory devices store data using memory cells with various configurations, such as that of DRAM, SRAM, FeRAM, flash memory, and similar. Of these, static RAM (SRAM) memory cells have a pair of cross-connected CMOS inverters and a pair of NMOS transmission transistors. Further, SRAM has a word driving circuit which drives word lines provided at each row, column selection gates provided at each column, sense amplifiers, write amplifiers, and other peripheral circuits, and these are also formed from CMOS circuits.

In general, the semiconductor substrate of an LSI having CMOS circuits has N-type well regions to form PMOS transistors and P-type well regions to form NMOS transistors. For example, at the surface of a P-type semiconductor transistor, deep N-type well regions are formed, and P-type well regions are formed within the deep N-type well regions. Or, at the surface of an N-type semiconductor substrate, deep P-type well regions are formed, and N-type well regions are formed within the deep P-type well regions. The ground voltage is supplied as a back gate voltage to the P-type well regions, and the power supply voltage is supplied as a back gate voltage to the N-type well regions, so that the PN junctions between each of the well regions and the source regions and drain regions within the well regions are kept at a reverse-direction potential.

There are many cases in which the source terminal of an NMOS transistor is connected to ground voltage, and so due to this configuration it is advantageous to apply ground voltage to the P-type well regions in which NMOS transistors are formed. Similarly, there are many cases in which the source terminal of a PMOS transistor is connected to the power supply voltage, and so due to this configuration it is advantageous to apply the power supply voltage to the N-type well regions in which PMOS transistors are formed.

The semiconductor memory device is enclosed in Japanese Patent Application Laid-open No. H10-173064, Japanese Patent Application Laid-open No. 2000-164819 and Japanese Patent Application Laid-open No. 2007-251173.

### SUMMARY

In recent years LSI microminiaturization techniques have shortened the channel lengths of MOS transistors, made gate insulating films thinner, lowered threshold voltages, and lowered power supply voltage potentials. Although microminiaturization techniques have raised integration levels and increased operation speeds, the occurrence of leakage currents of MOS transistors in the off state is a problem.

One method to suppress off-leakage currents of MOS transistors is to make the back gate voltage a potential different from the ground voltage and power supply voltage. That is, a P-type back gate voltage lower than the ground voltage is applied to the P-type well region in which an NMOS transistor is formed, or, an N-type back gate voltage higher than the power supply voltage is applied to the N-type well region in which a PMOS transistor is formed. By applying such a back-bias direction back gate voltage, the threshold voltages of NMOS transistors and PMOS transistors are each raised, and leakage currents in the off state are suppressed.

However, in order to suppress scattering in transistor characteristics between chips, the back gate voltages in P-type well regions and N-type well regions are controlled. For example, a transistor is designed in advance to have a low threshold voltage and fast characteristics, the back gate voltage in the back-bias direction is adjusted corresponding to the characteristics after manufacture, thereby adjusting the threshold voltage to be higher, and eliminating scattering in characteristics.

In this way, reduction of off-leakage currents of transistors is realized through a higher threshold voltage, and fast transistor characteristics are realized through a low threshold voltage, and so there is a trade-off between reduction of off-leakage currents and fast characteristics. That is, if the back gate voltage is adjusted to raise the threshold voltage so as to reduce off-leakage currents, speed is lowered, and if the back gate voltage is adjusted to lower the threshold voltage so as to increase speed, off-leakage currents increase.

It is preferable that, for example in a memory cell array, a back gate voltage be selected which raises the threshold voltage in order to suppress off-leakage currents, and that, in a peripheral circuit, a back gate voltage be selected which lowers the threshold voltage in order to increase speed. However, there are also cases in which the threshold voltage is set to an intermediate voltage in a peripheral circuit so as to enable suppression of off-leakage currents to some extent. As a result, memory cell array regions and peripheral circuit regions are to be divided into separate well regions, and layout efficiency tends to decline.

One aspect of the present embodiment is a semiconductor memory device, comprising:

a memory cell array in which are disposed a plurality of memory cells, each including a first conduction type transistor and a second conduction type transistor;

a peripheral circuit which includes the first conduction type transistor and the second conduction type transistor, and which controls access to memory cells in the memory cell array;

a first conduction type memory cell array well region, which is within the region of the memory cell array, and in which are formed the second conduction type transistors of the plurality of memory cells;

a second conduction type memory cell array well region, which is within the first conduction type memory cell array well region, and in which are formed the first conduction type transistors of the plurality of memory cells;

a first conduction type peripheral circuit well region, which is within the region of the peripheral circuit, and in which is formed the second conduction type transistor of the peripheral circuit;

a second conduction type peripheral circuit well region, which is within the first conduction type peripheral circuit well region, and in which is formed the first conduction type transistor of the peripheral circuit; and,

a second conduction type isolation region, which is disposed between the first conduction type memory cell array well region and the first conduction type peripheral circuit well region, wherein

at least a portion of first conduction type transistors of first conduction type transistors of the peripheral circuit is formed in the second conduction type isolation region.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of memory cells and column-side peripheral circuits of the semiconductor memory device of an embodiment.

FIG. 2 is a circuit diagram illustrating the memory cell array and the peripheral circuits of rows and columns in the semiconductor memory device of this embodiment.

FIG. 3 illustrates a schematic configuration of the memory cell array region on the semiconductor substrate of the semiconductor memory device in this embodiment.

FIG. 4 and FIG. 5 illustrate layouts of transistors in a memory cell array and column-side peripheral circuits of a semiconductor device of this embodiment.

FIG. 6 illustrates the example of back gate voltage lines within a memory macro.

FIG. 7 illustrates the cross-sectional structure of the memory macro depicted in the plane view of FIG. 6.

FIG. 8 illustrates the planar structure of the memory macro.

FIG. 9 is a cross-sectional view of the semiconductor memory device in a first embodiment.

FIG. 10 is a plane view of the semiconductor memory device in the first embodiment.

FIG. 11 is a cross-sectional view of the semiconductor memory device in a second embodiment.

FIG. 12 is a plane view of the semiconductor memory device in the second embodiment.

FIG. 13 is a cross-sectional view of the semiconductor memory device in a third embodiment.

FIG. 14 is a plane view of the semiconductor memory device in the third embodiment.

### DESCRIPTION OF EMBODIMENTS

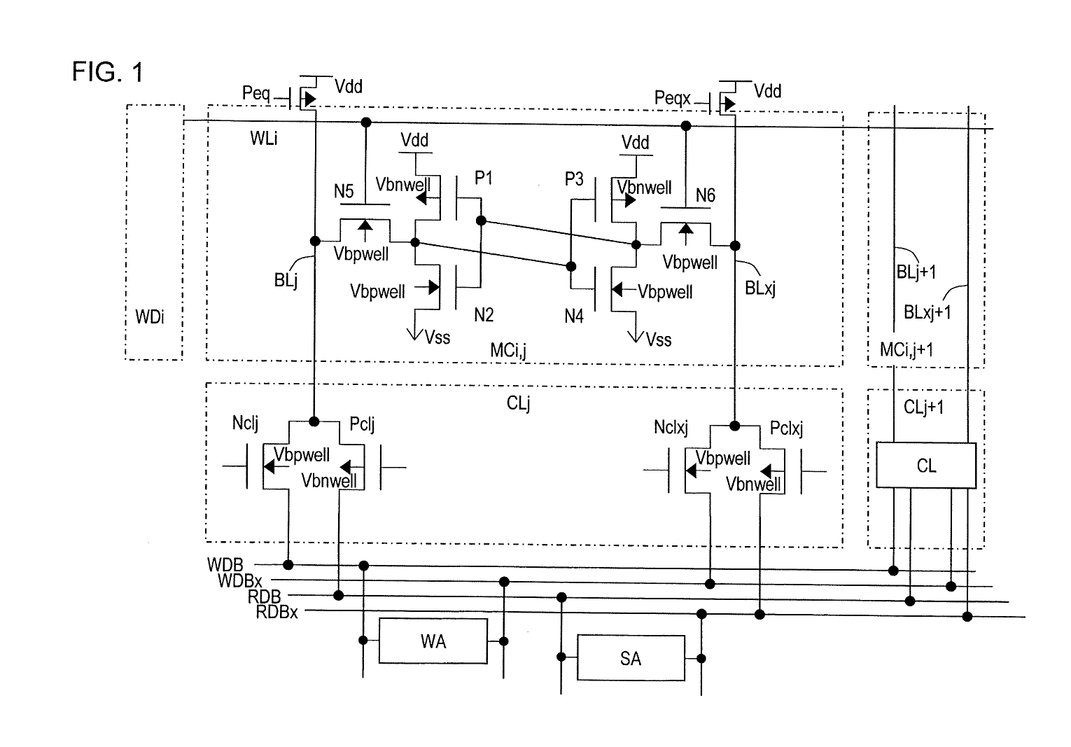

FIG. 1 illustrates an example of memory cells and column-side peripheral circuits of the semiconductor memory device of an embodiment. In FIG. 1, a word line WLi, bit lines BLj, BLxj, BLj+1, BLxj+1, memory cells MCi,j and MCi,j+1, and column selection circuits aj, CLj+1 of column-side peripheral circuits corresponding thereto, and a word driver circuit WDi of a row-side peripheral circuit, of a portion of the semiconductor memory device are illustrated; in addition, a sense amplifier SA, write amplifier WA, and data buses DB, DBx are illustrated as peripheral circuits.

The memory cell MCi,j has an inverter with a PMOS transistor P1 and NMOS transistor N2 connected between the power supply voltage Vdd and ground Vss, and an inverter having a PMOS transistor P3 and NMOS transistor N4 connected between the power supply voltage Vdd and ground Vss; the inputs and outputs of these inverters are cross-connected, and the pair of connection nodes are held at the H and L level potentials. The memory cell MCi,j has transmission transistors, comprising NMOS transistors N5 and N6, between the pair of connection nodes at which the inputs and outputs of the pair of inverters are cross-connected and the bit line pair BLj, BLxj, respectively. The gates of these NMOS transistors N5, N6 are connected to the word line WLi.

The bit line pair BLj, BLxj is provided with PMOS transistors Peq, Peqx which equalize the bit lines at the power supply voltage Vdd. By supplying an L level equalizing signal to the gates of the PMOS transistors, the bit line pair is equalized at the power supply voltage Vdd. And by causing the word driver circuit WDi to drive the word line WLi to H level, the potential of one of the bit line pair equalized at Vdd is lowered, according to the storage states of the row-direction memory cells. This lower potential is detected by a sense amplifier SA, described below, and readout is performed.

Further, the column-side peripheral circuit CLj is a column selection circuit, and includes NMOS transistors Nclj, Nclxj provided between the bit line pair BLj, BLxj and the write data bus line pair WDB, WDBx respectively, and PMOS transistors Pclj, Pclxj provided between the bit line pair BLj, BLxj and the readout data bus line pair RDB, RDBx respectively. The column-side peripheral circuit CLj+1 has a similar circuit configuration. The write data bus line pair WDB, WDBx provided in common for the plurality of bit line pairs is connected to the NMOS transistors Nclj, Nclxj and the write amplifier circuit WA, and similarly, the readout data bus line pair RDB, RDBx provided in common for the plurality of bit line pairs is connected to the PMOS transistors Pclj, Pclxj and the sense amplifier SA.

The sense amplifier SA and write amplifier WA are also circuits which combine CMOS inverters. The sense amplifier SA detects a drop in the potential of one among the selected bit line pair and the readout data bus line pair. The write amplifier WA forcibly lowers the potential of one among the selected bit line pair and the write data bus line pair, and inverts the memory cell latch circuit.

The word driver circuit WDi, which is a row-side peripheral circuit comprising CMOS inverters, described below, drives a word line selected by a word decoder, not illustrated, to H level, and drives an unselected word line to L level.

The memory cell array of the semiconductor memory device includes memory cells MC disposed in an array of for example m rows and n columns, word lines WL for m rows, and bit line pairs BL, BLx for n columns. The numbers of the memory cells, word lines, and bit line pairs of the memory cell array differ according to the data storage capacity of the semiconductor memory device.

The memory cell array having a plurality of memory cells and the peripheral circuits include NMOS transistors of a first conduction type (N type) and PMOS transistors of a second conduction type (P type). Hence the semiconductor substrate on which the semiconductor memory device is formed includes P-type well regions in which NMOS transistors are formed, and N-type well regions in which PMOS transistors are formed.

The N-type back gate voltage Vbnwell of PMOS transistors in the memory cells MC of this embodiment is a voltage Vdd+Vn1 higher than the power supply voltage Vdd, or is dynamically controlled at a voltage Vdd+Vn1 higher than the power supply voltage Vdd. And, the P-type back gate voltage Vbpwell of NMOS transistors in the memory cells MC of this embodiment is a negative voltage Vss−Vp1 lower than ground voltage Vss, or is dynamically controlled at a voltage Vss−Vp1 lower than ground voltage Vss. By thus controlling the back gate voltages, the threshold voltage Vthn1, Vthp1 of the NMOS and PMOS transistors in memory cells are raised, and off-leakage currents are reduced.

However, the N-type back gate voltage Vbnwell of the PMOS transistors in the peripheral circuits is a voltage Vdd+Vn2 (Vn2<Vn1) higher than the power supply voltage Vdd, or is dynamically controlled at a voltage Vdd+Vn2 higher than the power supply voltage Vdd. However, the voltage is lower than the N-type back gate voltage of PMOS transistors in memory cells, so that the threshold voltage Vthp2 of the PMOS transistors in the peripheral circuits is made lower than Vthp1 (the absolute value of the threshold is made lower), to emphasize fast operation rather than suppression of off-leakage currents. Similarly, the P-type back gate voltage Vbpwell of NMOS transistors in the peripheral circuits is a negative voltage Vss−Vp2 (Vp2<Vp1) lower than ground voltage Vss, or is dynamically controlled at a voltage Vss−Vp2 lower than ground voltage Vss. However, the voltage is a negative voltage less negative than that for NMOS transistors in memory cells, so that the threshold voltage Vthn2 of the NMOS transistors in the peripheral circuits is made lower than Vthn1, to emphasis fast operation rather than suppression of off-leakage currents.

Thus the back gate voltages in the memory array are controlled at voltages to make the absolute value of the threshold voltage higher, emphasizing off-leakage current reduction, while the back gate voltages in peripheral circuits are controlled to a voltage emphasizing fast operation such that the absolute value of the threshold voltage is lower than that for memory cells.

Hence in the semiconductor memory device of this embodiment, lines for the N-type back gate voltage Vbnwell and lines for the P-type back gate voltage Vbpwell are provided on the semiconductor substrate in the memory cell array and in the peripheral circuits, separately from the lines for the power supply voltage Vdd and ground Vss. Further, the back gate voltages are made different in the memory cell array and in the peripheral circuits, and lines for these are also provided separately.

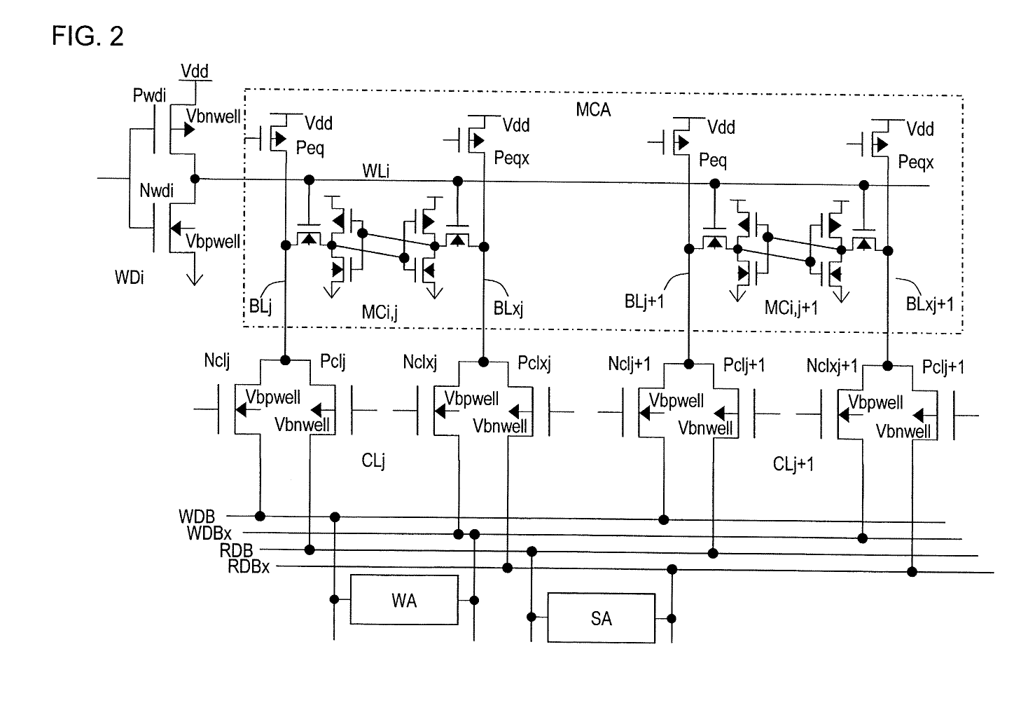

FIG. 2 is a circuit diagram illustrating the memory cell array and the peripheral circuits of rows and columns in the semiconductor memory device of this embodiment. In the circuit diagram of FIG. 2, the configuration of the memory cells and column-side peripheral circuit is the same as in FIG. 1. FIG. 2 differs from FIG. 1 in that the specific configuration of the word driver circuit WDi is illustrated, and memory cells MCi,j, MCi,j+1 in two columns and the column selection circuits CLj, CLj+1 corresponding thereto are illustrated.

The word driver circuit WDi is a CMOS inverter circuit comprising a PMOS transistor Pwdi and an NMOS transistor Nwdi. The word driver circuit WD corresponding to a selected word line WL takes as input an L level selection signal from a word decoder, not illustrated, and the PMOS transistor Pwd conducts to drive the word line WL to the potential of the power supply voltage Vdd. The word driver circuit WD corresponding to an unselected word line WL takes as input an H level non-selection signal, and the NMOS transistor Nwd conducts to drive the word line WL to ground voltage Vss. Hence in operation states other than readout and write operation, the PMOS transistor Pwd in the word driver circuit WD is not conducting, the NMOS transistor Nwd is conducting, and all the word lines WL are maintained at ground potential.

In a readout operation, all of the bit line pairs BL, BLx are equalized at the H level potential of the power supply voltage Vdd in advance by making the PMOS transistors for equalizing Peq, Peqx conducting, the selected word line WL is driven to the potential of the power supply voltage Vdd by the word driver circuit WD, the transmission transistors in the memory cells are made conducting, and potential of one of the bit lines falls according to the storage state in a memory cell.

The PMOS transistors Pcl, Pclx in the selected column selection circuit CL are made conducting, and a selected bit line pair is connected via the readout data bus line pair RDB, RDBx to the sense amplifier SA. The sense amplifier SA detects the fall in potential of one among the bit line pair equalized at the power supply voltage Vdd. The PMOS transistor in the column selection circuit is advantageous in order to transmit a potential change at the bit line which has fallen from the high potential Vdd in this way.

In a write operation, all of the bit lines BL, BLx are equalized at potential of the power supply voltage Vdd in advance by making the PMOS transistors for equalizing Peq, Peqx conducting, the word line WL selected by the word driver circuit WD is driven to the potential of the power supply voltage Vdd by the word driver circuit WD, and the transmission transistors in the memory cells are made conducting. The NMOS transistors Ncl, Nclx in the selected column selection circuit CL are made conducting, the write amplifier WA lowers the potential of the bit line corresponding to the write data, and the write data is stored in the memory cell. The NMOS transistors Ncl, Nclx which continue to conduct even when the bit line potential is lowered are advantageous among the transistors in the column selection circuits for the operation by the write amplifier WA to lower the bit line potential.

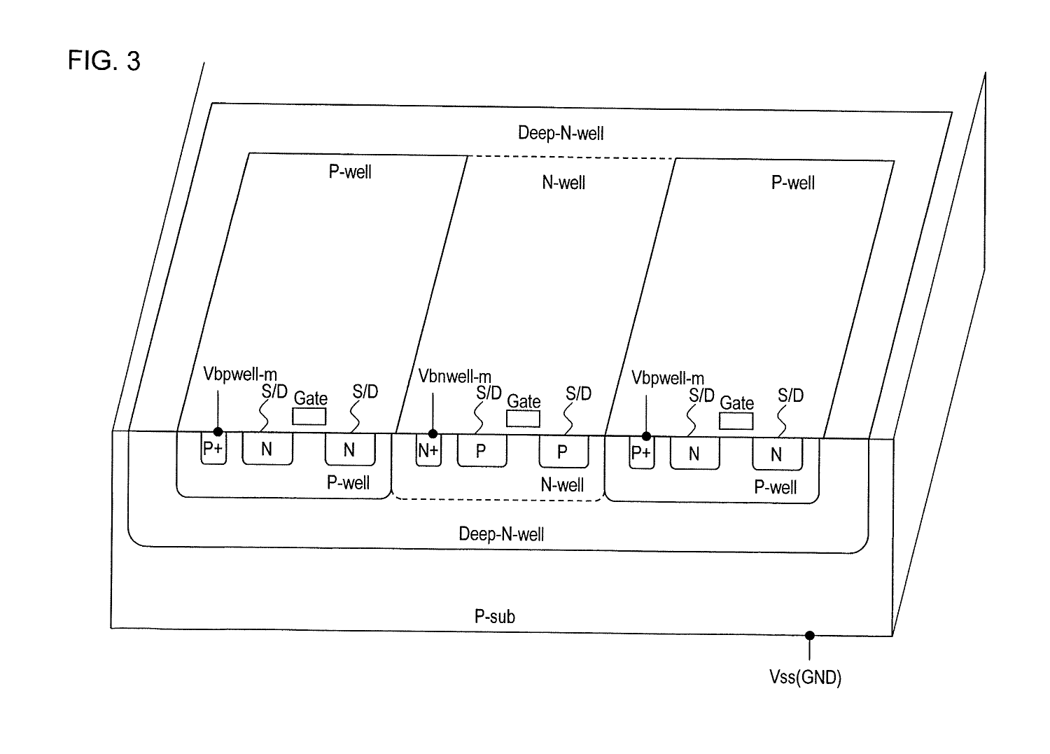

FIG. 3 illustrates a schematic configuration of the memory cell array region on the semiconductor substrate of the semiconductor memory device in this embodiment. In this example, a comparatively deep N-type well region Deep-N-well is formed in the P-type semiconductor substrate P-sub, and a plurality of P-type well regions shallower than the deep-N-well, P-well, are formed within this deep N-type well region Deep-N-well. The regions between the P-type well regions P-well are N-type well regions N-well.

An N-type well region N-well is shallower than the deep N-type well region Deep-N-well; the shallow region of the deep N-type well region Deep-N-well may be used without modification, or N-type impurities may be implanted to form a shallow region in the deep N-type well region Deep-N-well. Further, it is sufficient that the P-type well regions P-well be provided within the deep N-type well region Deep-N-well, and a deep N-type well region N-well is not provided below the shallow N-type well regions N-well.

In the P-type well regions P-well in the memory cell array region, N-type source/drain regions S/D and P-type well contact regions P+ for application of the P-type back gate voltage Vbpwell-m are formed, and gate electrodes Gate are formed on the substrate between source/drain regions S/D with a gate oxide film, not illustrated, interposed. A line to supply the P-type back gate voltage Vbpwell-m is connected to the P-type well contact regions P+.

In the N-type well regions N-well in the memory cell array region, P-type source/drain regions S/D and N-type well contact regions N+ for application of the N-type back gate voltage Vbnwell-m are formed, and gate electrodes Gate are formed on the substrate between source/drain regions S/D with a gate oxide film, not illustrated, interposed. A line to supply the N-type back gate voltage Vbnwell-m is connected to the N-type well contact regions N+.

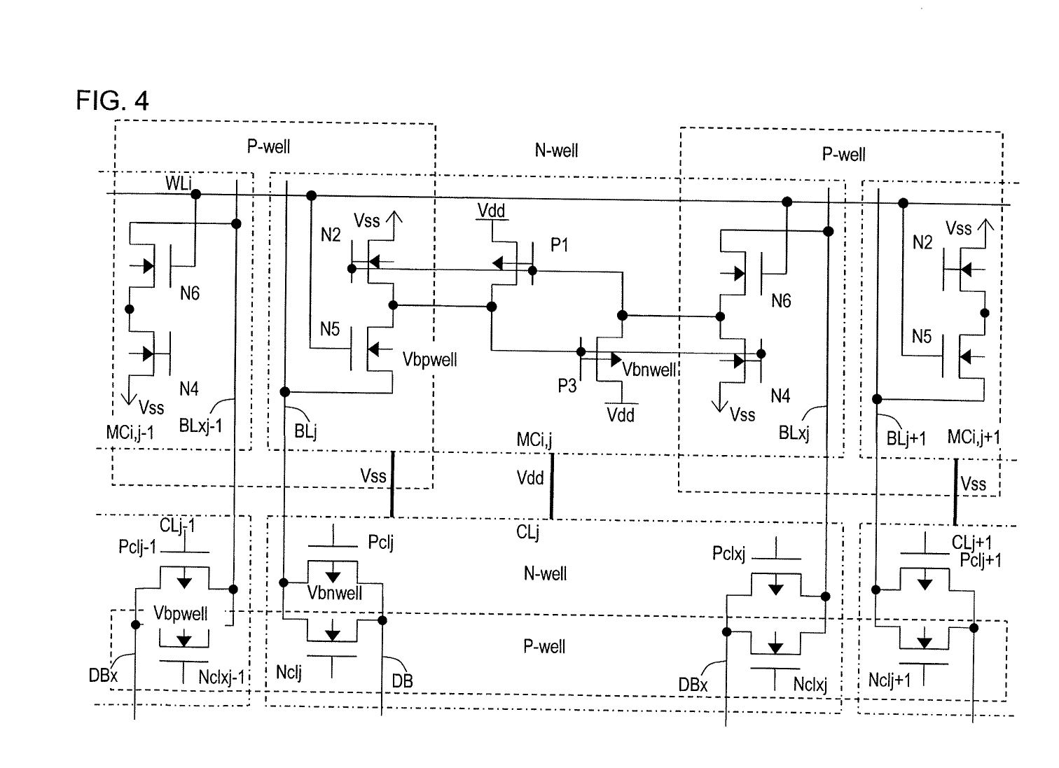

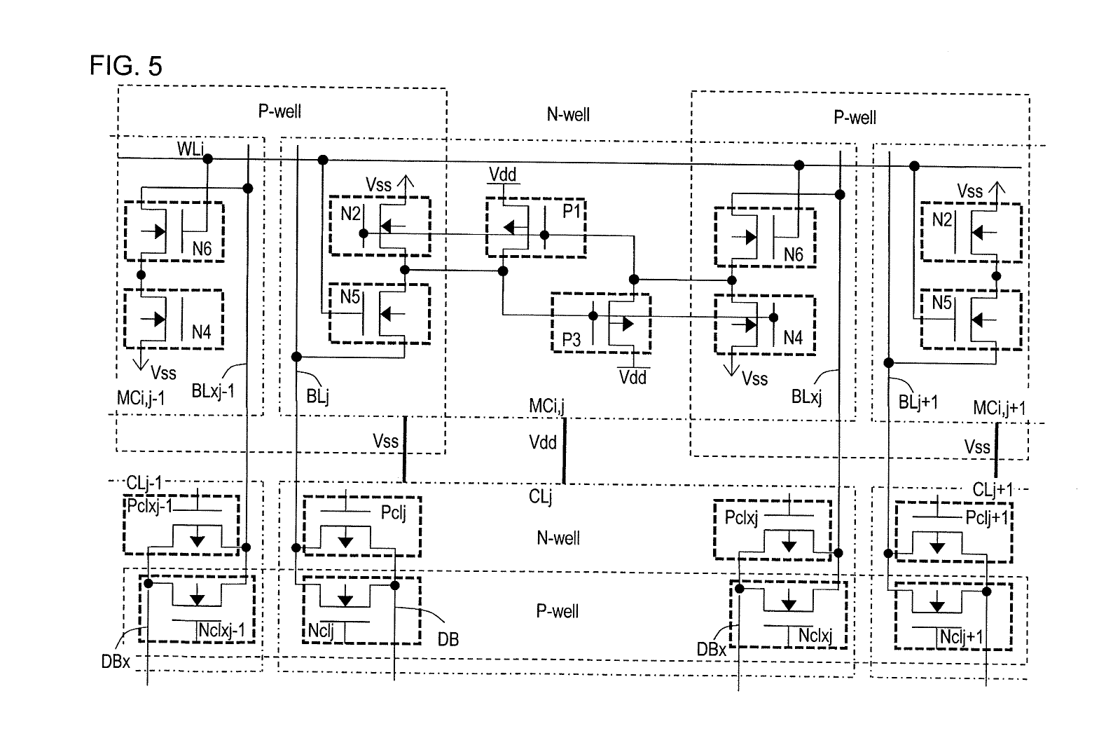

FIG. 4 and FIG. 5 illustrate layouts of transistors in a memory cell array and column-side peripheral circuits of a semiconductor device of this embodiment. FIG. 4 illustrates, instead of a specific layout, the disposition in P-type well regions P-well and N-type well regions N-well, indicating the positional relationship of NMOS transistors and PMOS transistors. FIG. 5 uses broken-line rectangles to indicate the regions of MOS transistors in the circuit diagram of FIG. 4. The circuit configuration is the same in FIG. 4 and FIG. 5.

As explained using FIG. 3, three P-type well regions P-well are disposed in the N-type well region N-well in the plane view of FIG. 4. The P-type well regions P-well on the left and right are isolated regions enclosed by N-type well regions in the memory cell array. The P-type well region P-well on the lower side is formed in the column-side peripheral circuits, and is an isolated region enclosed by N-type well regions. P-type well regions P-well are indicated by dashed lines.

FIG. 4 depicts three memory cells MCi,j−1, MCi,j, MCi,j+1, disposed in the row direction. The region of the three memory cells is indicated by dot-dash lines. FIG. 4 depicts three column selection circuits CLj−1, CLj, CLj+1 as column-side peripheral circuits; the regions of these three column selection circuits are also indicated by dot-dash lines.

The two PMOS transistors P1, P3 in the memory cell MCi,j illustrated in FIG. 1 are disposed within an N-type well region N-well. Of the four NMOS transistors, two NMOS transistors N2, N5 are disposed in the left-side P-type well region P-well, and the remaining two NMOS transistors N4, N6 are disposed in the right-side P-type well region P-well. The two NMOS transistors N4, N6 in the memory cell MCi,j−1 adjacent on the left are disposed in the left-side P-type well region P-well, and the two NMOS transistors N2, N5 in the memory cell MCi,j+1 adjacent on the right are disposed in the right-side P-type well region P-well.

Thus as illustrated in FIG. 4, in a memory cell array, a plurality of P-type well regions P-well extending in the column direction are arranged in a strip shape in the row direction. The region of one memory cell MC comprises one-half of the regions of P-type well regions P-well on the left and right, and the region of the N-type well region N-well therebetween; four NMOS transistors and two PMOS transistors are disposed within the P-type well regions P-well and the N-type well region N-well.

The column selection circuit CLj which is a column-side peripheral circuit has a pair of PMOS transfer gates for reading and a pair of NMOS transfer gates for writing, as explained using FIG. 1. That is, a PMOS transfer gate having a PMOS transistor Pclj connecting the bit line BLj to the read data bus RDB, and a PMOS transfer gate having a PMOS transistor Pclxj connecting the bit line BLxj to the read data bus RDBx, are provided. Further, an NMOS transfer gate having an NMOS transistor Nclj connecting the bit line BLj to the write data bus WDB, and an NMOS transfer gate having an NMOS transistor Nclxj connecting the bit line BLxj to the write data bus WDBx, are provided.

And, as illustrated in FIG. 4, in the region of a column selection circuit, a P-type well region P-well extending in the row direction is provided within the N-type well-region N-well, and within the column selection circuit CLj, two PMOS transistors Pclj, Pclxj are disposed within the N-type well region N-well and two NMOS transistors Nclj, Nclxj are disposed within the P-type well region P-well.

Further, two bit lines BLj, BLxj, a ground line Vss, and a power supply line Vdd are provided, disposed in the column direction from the memory cell MCi,j to the column selection circuit CLj corresponding thereto. Although not illustrated, the ground line Vss and power supply line Vdd are disposed extending in the vertical direction, that is in the column direction, within the memory cell array. Hence four lines are formed between the memory cell array group disposed in the column direction and the column selection circuit CL corresponding thereto.

Although not illustrated in FIG. 4 and FIG. 5, a contact structure for the N-type back gate voltage Vbnwell is provided in the N-type well region N-well, and the N-type back gate voltage Vbnwell and N-type well region N-well are connected. And, this N-type back gate voltage line has a line for the memory cell array and a line for the peripheral circuit, which are controlled at different back gate voltages. Similarly, a contact structure for the P-type back gate voltage Vbpwell is provided within the P-type well region P-well, and the P-type back gate voltage Vbpwell and P-type well region P-well are connected. And, this P-type back gate voltage line has a line for the memory cell array and a line for the peripheral circuit, which are controlled at different back gate voltages.

[Examples of Back Gate Voltage Lines in a Memory Macro]

Next, an example of back gate voltage lines within a memory macro is explained. A characteristic of SRAM is high-speed access. And, a system LSI has internally a plurality of SRAM memory macros. However, the memory data capacity differs according to the functions of the circuits requiring the memory macros. A memory macro for which a large data capacity is demanded has numerous memory cells. Conversely, a memory macro for which a small data capacity suffices has a small number of memory cells.

It is desirable that the area of memory macros embedded within a system LSI be made as small as possible.

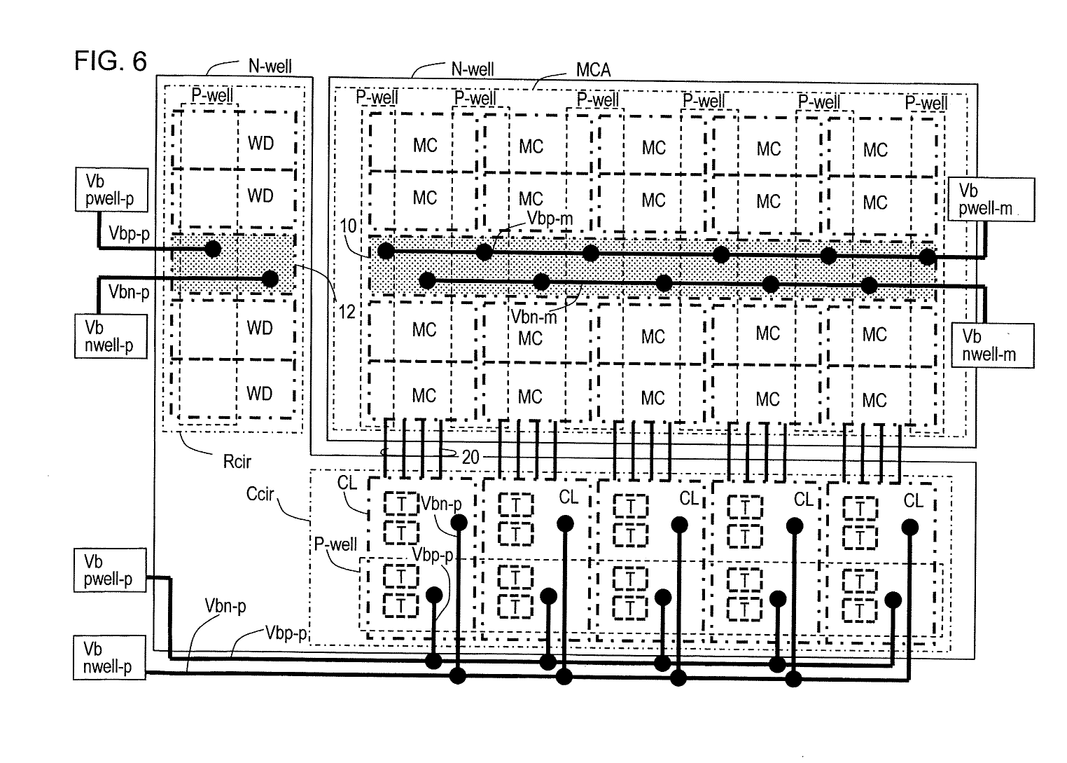

FIG. 6 illustrates the example of back gate voltage lines within a memory macro. The memory macro has a memory cell array MCA having memory cells MC in four rows and five columns, a row-side peripheral circuit Rcir having four rows of word drivers WD, and a column-side peripheral circuit Ccir having five columns of column selection circuits CL. The memory macro has, in the region of the memory cell array MCA, an N-type well region N-well, and provided therewithin, a plurality of P-type well regions P-well. Similarly, the regions of the peripheral circuits Rcir and Ccir each have an N-type well region N-well and a plurality of P-type well regions P-well provided therewithin. As explained above, different voltages are supplied as the back gate voltage Vbnwell-m of the N-type well region N-well of the memory cell array and the back gate voltage Vbnwell-p of the N-type well regions N-well of the peripheral circuits, and thus lines are formed separately.

Within the memory cell array MCA, six P-type well regions P-well (broken lines) extending in the column direction are provided in the N-type well region N-well, and the memory cells MC (dot-dash lines) in four rows and five columns each have P-type well regions P-well on both sides and an N-type well region N-well therebetween, with the NMOS transistors and PMOS transistors constituting the memory cells disposed.

Further, the row-side peripheral circuit Rcir has, within the N-type well region N-well, one P-type well region P-well (broken line) extending in the column direction and in an N-type well region N-well, and within both well regions, NMOS transistors and PMOS transistors constituting word driver circuits are disposed.

The column-side peripheral circuit Ccir has, within the same N-type well region N-well as the row-side peripheral circuit, a P-type well region P-well (broken line) extending in the row direction and in an N-type well region N-well, and NMOS transistors and PMOS transistors (“T” in the figure) constituting column selection circuits are disposed.

The pitch of memory cells MC in the column direction and the pitch of word driver circuits WD in the column direction are identical. The pitch of memory cells MC in the row direction and the pitch of column selection circuits CL in the row direction are identical.

The back gate voltage lines Vbp, Vbn are laid out as follows. First, in the memory cell array MCA, a well contact region 10 (gray in the figure) for disposition of a connection structure with the back gate voltage lines is provided in the memory cell array, and on the well contact region 10 are disposed a line Vbn-m for the N-type back gate voltage Vbnwell-m and a line Vbp-m for the P-type back gate voltage Vbpwell-m; then, structures (black circles in the figure) for connection to the well regions N-well, P-well are disposed corresponding to the lines Vbn-m, Vbp-m.

In the row-side peripheral circuit Rcir also, a well contact region 12 is disposed at a position corresponding to the well contact region 10 between the word drivers WD. In the well contact region 12 also, a line Vbn-p for the N-type back gate voltage Vbnwell-p and a line Vbp-p for the P-type back gate voltage Vbpwell-p are disposed, and structures (black circles in the figure) for connection to the well regions N-well, P-well are disposed corresponding to the lines Vbn-p, Vbp-p.

In the column-side peripheral circuit Ccir are disposed column selection circuits CL corresponding to each of the columns of the memory cell array. In the example of FIG. 6, the pitch of memory cells in the row direction and the pitch of column selection circuits CL are the same, and the positions match. In each of the regions of the column selection circuits CL are disposed a line Vbp-p of the P-type back gate voltage Vbpwell-p and a line Vbn-p of the N-type back gate voltage Vbnwell-p, extending in the column direction, as well as contact structures (black circles) for these.

The back gate voltage lines Vbp-m, Vbn-m disposed in the memory cell array respectively supply a voltage Vdd+Vn1 higher than the power supply voltage Vdd and a voltage Vss−Vp1 lower than ground Vss, respectively generated by voltage generation circuits Vbnwell-m, Vbpwell-m provided outside the memory macro, to the P-type well regions (P-type memory cell array well regions) P-well and to the N-type well region (N-type memory cell array well region) N-well, within the memory cell array.

However, the back gate voltage lines Vbp-p, Vbn-p disposed in the peripheral circuits respectively supply a voltage Vdd+Vn2 (Vn2<Vn1) higher than the power supply voltage Vdd and a low voltage Vss−Vp2 (Vp2<Vp1) lower than ground Vss, respectively generated by voltage generation circuits Vbnwell-p, Vbpwell-p provided outside the memory macro, to the P-type well regions (P-type peripheral circuit well regions) P-well and N-type well regions (N-type peripheral circuit well regions) N-well, within the peripheral circuits.

[Cross-Sectional Structure of Memory Macro in this Embodiment]

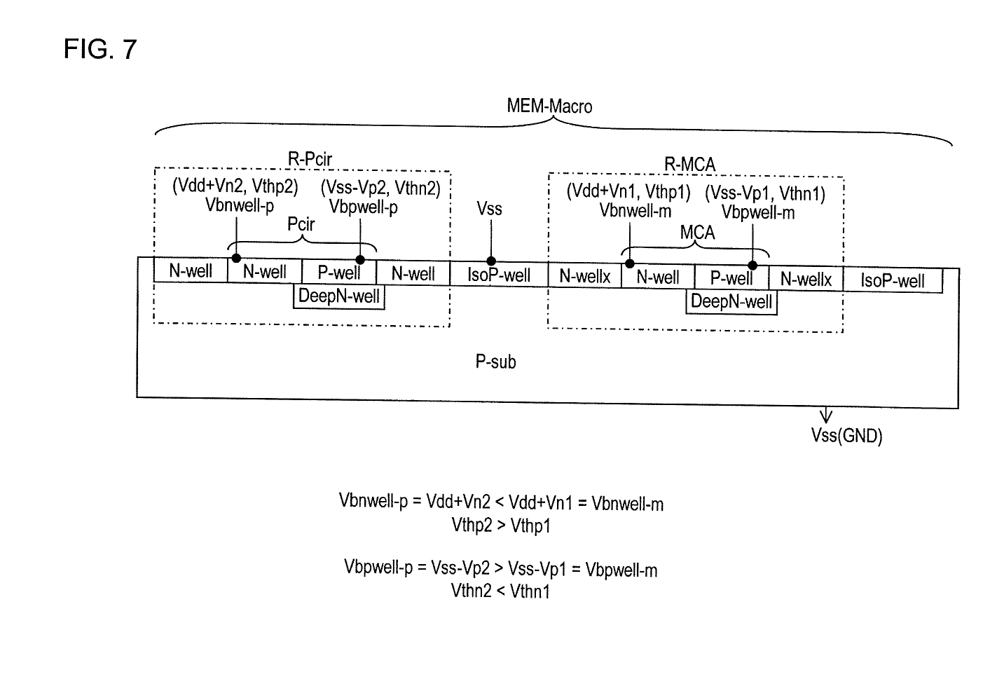

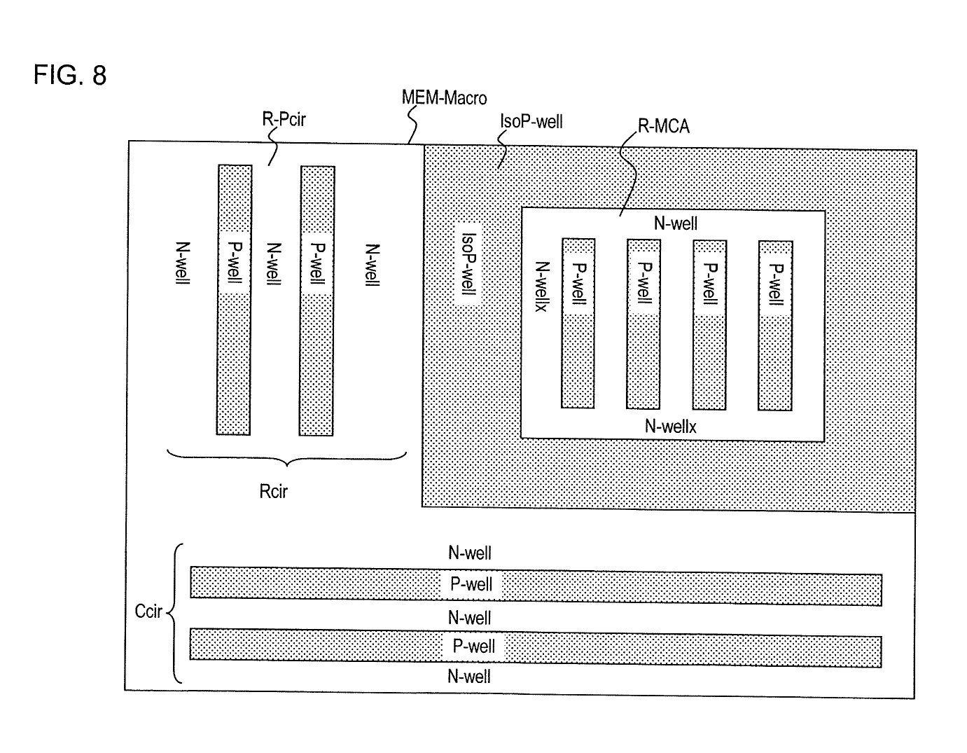

FIG. 7 illustrates the cross-sectional structure of the memory macro depicted in the plane view of FIG. 6. FIG. 8 illustrates the planar structure of the memory macro. As explained in FIG. 3 and FIG. 6, the memory macro has a deep N-type well region DeepN-well provided on the P-type semiconductor substrate P-sub, a P-type well region P-well provided therein on the substrate surface, and an N-type well region N-well on the substrate surface contiguous with the deep N-type well region DeepN-well.

As illustrated in FIG. 7, the back gate voltage Vbnwell-m for the N-type well region N-well within the memory cell array region R-MCA is Vdd+Vn1, and the PMOS transistors provided therein have as the threshold voltage value a high first PMOS threshold voltage Vthp1, so that off-leakage currents are adequately suppressed. The back gate voltage Vbpwell-m for the P-type well region P-well within the memory cell array region R-MCA is Vss−Vp1, and the NMOS transistors provided therein also have as the threshold voltage value a high first NMOS threshold voltage Vthn1, so that off-leakage currents are adequately suppressed.

However, the back gate voltage Vbnwell-p for the N-type well regions N-well within the peripheral circuit regions R-Pcir is Vdd+Vn2 (Vn1>Vn2), and Vdd+Vn2<Vdd+Vn1, and the PMOS transistors provided therein have a second PMOS threshold voltage Vthp2 (>Vthp1) the absolute value of which is lower than the first PMOS threshold value Vthp1, so that faster operation characteristics are obtained, and suppression of off-leakage currents is somewhat weakened. Further, the back gate voltage Vbpwell-p for the P-type well regions P-well in the peripheral circuit regions R-Pcir is Vss−Vp2 (Vp1>Vp2), so that Vss−Vp2>Vss−Vp1, and the NMOS transistors provided therein have a second NMOS threshold voltage Vthn2 (<Vthn1) the absolute value of which is lower than the first NMOS threshold voltage Vthn1, so that faster operation characteristics are obtained, and suppression of off-leakage currents is somewhat weakened.

Thus the back gate voltages Vbpwell-m, Vbnwell-m for the memory cell array and the back gate voltages Vbpwell-p, Vbnwell-p for the peripheral circuits are different voltages. Hence the deep N-type well region DeepN-well and the N-type well regions N-well contiguous therewith within the memory cell array region R-MCA are electrically isolated, by separation with a P-type well region for isolation IsoP-well, from the deep N-type well region DeepN-well and the N-type well regions N-well contiguous therewith within the peripheral circuit region R-Pcir. The deep N-type well region DeepN-well is formed by deep implantation of N-type impurities into the substrate, and so is spread out in the substrate surface directions. Consequently the P-type well region for isolation IsoP-well is sufficiently wide. The ground voltage Vss is applied to the P-type semiconductor substrate P-sub, and so the ground voltage Vss is also applied to the P-type well region P-well for isolation.

The plane view of FIG. 8 illustrates, similarly to FIG. 6, the plurality of P-type well regions P-well within the N-type well region N-well in the memory cell array region R-MCA, and the plurality of P-type well regions P-well within the N-type well region N-well in the peripheral circuit region R-Pcir. However, in the cross-sectional view of FIG. 7, the P-type well regions P-well are simplified, and only one regions each is depicted in the memory cell array region R-MCA and in the peripheral circuit region R-Pcir.

As illustrated in the cross-sectional view of FIG. 7, the back gate voltages Vbnwell-m, Vbpwell-m are supplied to the N-type well regions N-well and P-type well region P-well in which are respectively formed the PMOS transistors and the NMOS transistors of the memory cell array MCA within the memory cell array region R-MCA. Further, in FIG. 7, on both sides of the N-type well region N-well and the P-type well regions P-well forming the memory cell array MCA, illustrated are the N-type well regions N-wellx corresponding to the peripheral regions of the N-type well regions N-well surrounding the plurality of P-type well regions P-well within the memory cell array region R-MCA in the plane view of FIG. 8.

However, as illustrated in the cross-sectional view of FIG. 7, the back gate voltages Vbnwell-p, Vbpwell-p are supplied to the N-type well regions N-well and P-type well region P-well in which PMOS transistors and NMOS transistors of the peripheral circuit Pcir are respectively formed in the peripheral circuit region R-Pcir. Further, in FIG. 7, on both sides of the N-type well regions N-well and P-type well region P-well forming the peripheral circuit Pcir, the N-type well regions N-well are illustrated corresponding to the peripheral regions of the N-type well regions N-well surrounding the plurality of P-type well regions P-well within the peripheral circuit region R-Pcir in the plane view of FIG. 8.

As illustrated in the plane view of FIG. 8, first, the P-type well region for isolation IsoP-well, provided to electrically isolate the N-type well region N-well of the memory cell array region R-MCA and the N-type well regions N-well of the peripheral circuit region R-Pcir, is a factor increasing the area of the memory macro. In particular, it is important for the P-type well region for isolation IsoP-well to be of greater area than when isolating an ordinary shallow N-type well region, in order to isolate the deep N-type well region DeepN-well on the memory cell array region side and the deep N-type well region DeepN-well on the peripheral circuit region side.

Second, in the vicinity of the plurality of P-type well regions P-well provided within the N-type well region N-well of the memory cell array region R-MCA, it is necessary to provide an N-type well region N-wellx in the vicinity for isolation from the P-type well region IsoP-well for isolation. This N-type well region N-wellx in the vicinity is also a factor increasing the area of the memory macro.

In order to decrease the size of the memory macro, it is important to alleviate the reduction in area efficiency of the P-type well region for isolation IsoP-well and the N-type well region N-wellx in the vicinity, which are the two factors described above causing increases in area.

### First Embodiment

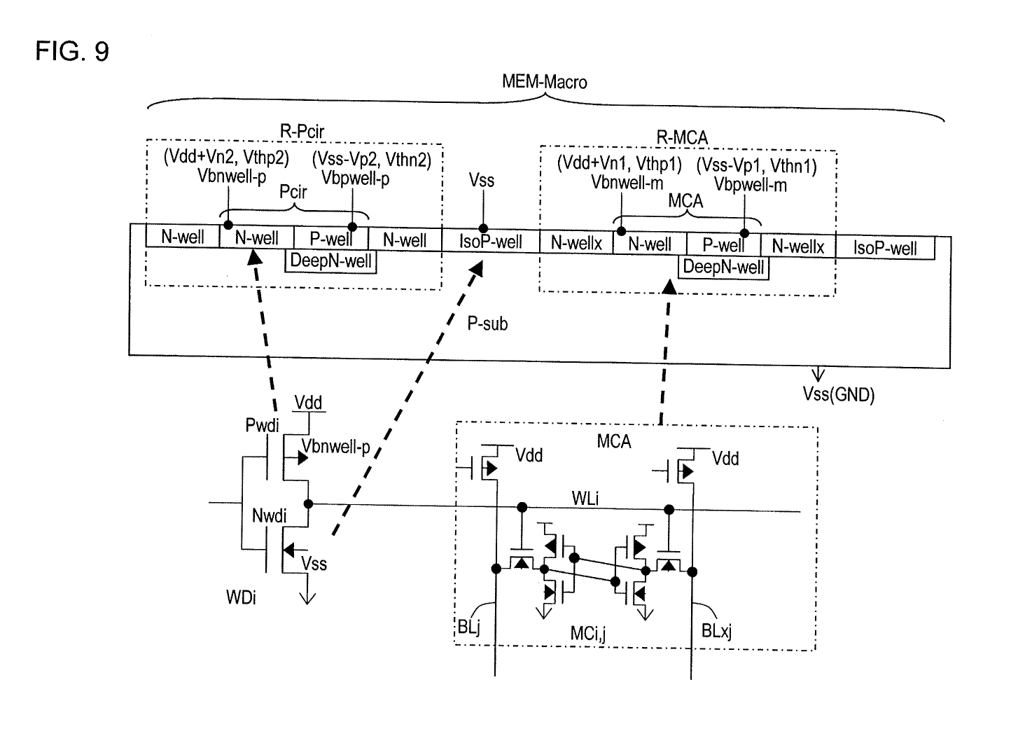

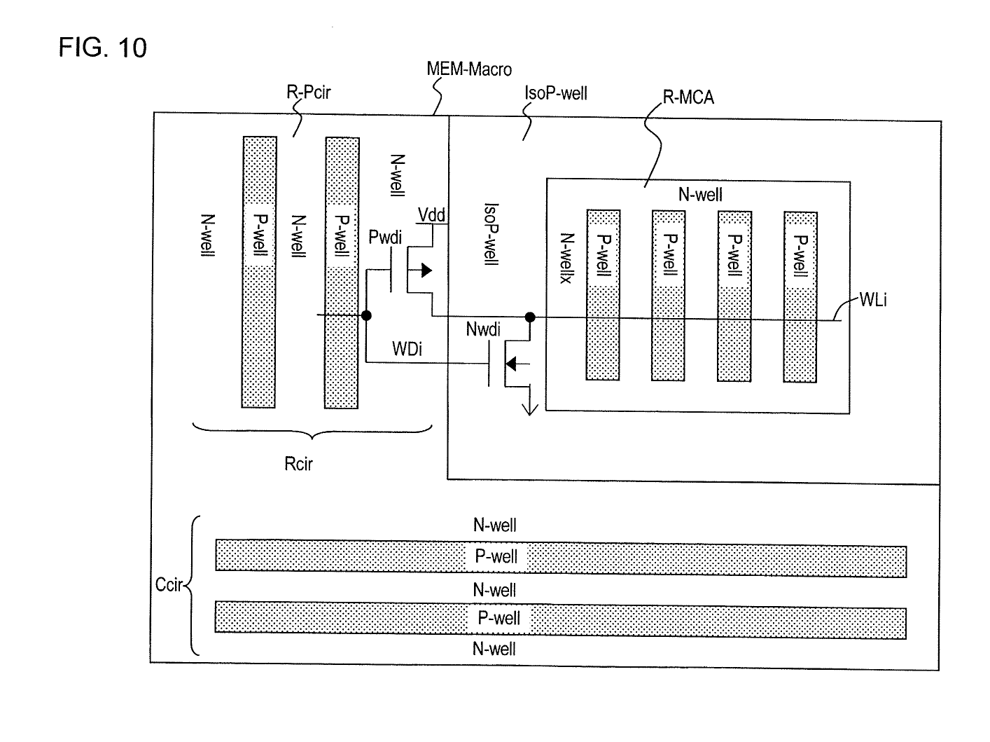

FIG. 9 is a cross-sectional view of the semiconductor memory device in a first embodiment. FIG. 10 is a plane view of the semiconductor memory device in the first embodiment. In the first embodiment, the NMOS transistors

Nwdi in the word driver circuits WDi of the row-side peripheral circuits which are peripheral circuits Pcir are provided within the P-type well region for isolation IsoP-well. Further, the PMOS transistors Pwdi in the word driver circuits WDi are provided in the N-type well regions N-well in the peripheral circuit region R-Pcir.

To repeat the explanations of FIG. 7 and FIG. 8, the back gate voltage Vbnwell-m for the N-type well regions N-well in the memory cell array region R-MCA is Vdd+Vn1, the PMOS transistors provided therein have a first PMOS threshold voltage Vthp1 with a high absolute value, and off-leakage currents are adequately suppressed. Further, the back gate voltage Vbpwell-m for the P-type well region P-well in the memory cell array region R-MCA is Vss−Vp1, the NMOS transistors provided therein have a first NMOS threshold voltage Vthn1 with a high absolute value, and off-leakage currents are adequately suppressed.

On the other hand, the back gate voltage Vbnwell-p for the N-type well regions N-well in the peripheral circuit region R-Pcir is Vdd+Vn2 (Vn1>Vn2), so that Vdd+Vn2<Vdd+Vn1, the PMOS transistors provided therein have a second PMOS threshold voltage Vthp2 (>Vthp1) the absolute value of which is lower than the first PMOS threshold voltage Vthp1, so that faster operation characteristics are obtained, and suppression of off-leakage currents is somewhat weakened. And, the back gate voltage Vbpwell-p for the P-type well region P-well in the peripheral circuit region R-Pcir is Vss−Vp2 (Vp1>Vp2), so that Vss−Vp2>Vss−Vp1, the NMOS transistors provided therein have a second NMOS threshold voltage Vthn2 (<Vthn1) the absolute value of which is lower than the first NMOS threshold voltage Vthn1, so that faster operation characteristics are obtained, and suppression of off-leakage currents is somewhat weakened.

During a readout operation and write operation, in word driver circuits WDi the PMOS transistors Pwdi are maintained in the conducting state and the NMOS transistors Nwdi are put into the non-conducting state in order to drive the selected word line WLi to the power supply level Vdd or to H level. And in a standby operation state other than a readout operation or write operation, the PMOS transistors Pwdi are put into the non-conducting state and the NMOS transistors Nwdi are put into the conducting state in order to drive all the word lines WLi to ground potential Vss or to L level.

Hence in the standby operation state which is the state of the device most of the time, the PMOS transistors Pwdi are put into the non-conducting state, therefore it is more greatly important to suppress off-leakage currents, whereas the NMOS transistors Nwdi are in the conducting state, and so there is little importance to suppress off-leakage currents. Hence it is desirable that PMOS transistors Pwdi be provided in N-type well regions N-well in the peripheral circuit region R-Pcir, and that the second PMOS threshold voltage Vthp2 be used by means of the back gate voltage Vbpwell-p (=Vdd+Vp2), which gives priority to fast transistor characteristics but also gives some priority to suppression of off-leakage currents. However, there is little importance to suppress off-leakage currents in NMOS transistors Nwdi, which may be provided in the P-type well region for isolation IsoP-well, and a back gate voltage Vss used so that the threshold voltage Vthn3 has an absolute value lower than the second PMOS threshold voltage Vthn2 (Vthp3<Vthp2<Vthp1), and off-leakage currents increase. By providing the transistors in the P-type well region for isolation IsoP-well, the P-type well region for isolation IsoP-well can be used effectively, and area efficiency is improved.

The characteristics of the NMOS transistors Nwdi in word driver circuits WDi are fast characteristics at a low threshold voltage Vthn3 due to the back gate voltage Vss, but to this extent the transistor gate width is decreased and the transistor size can be reduced. Further, the gate load capacitance is decreased, and to this extent operation is faster. The NMOS transistors Nwdi in word driver circuits WDi are conducting when the word line is not selected, and thus although there is scattering in characteristics on the fast operation side due to the back gate voltage Vss, conduction timing is for non-selected operations, and therefore some degree of scattering does not pose a problem.

PMOS transistors and NMOS transistors in the memory cell array are provided in the N-type well regions N-well and P-type well regions P-well in the memory cell array region R-MCA, and the absolute values of the respective threshold voltages Vthp1, Vthn1 are made sufficiently high through the back gate voltages Vbnwell-m (=Vdd+Vn1) and Vbpwell-m (=Vss−Vp1), which place highest priority on suppressing off-leakage currents.

In this way, by disposing in the P-type well region for isolation IsoP-well NMOS transistors Nwdi in word driver circuits WDi, which are NMOS transistors in peripheral circuits and which conduct in states other than readout operations and write operations, the P-type well region for isolation IsoP-well is used and area efficiency is raised without adverse effects on operation characteristics of peripheral circuits.

### Second Embodiment

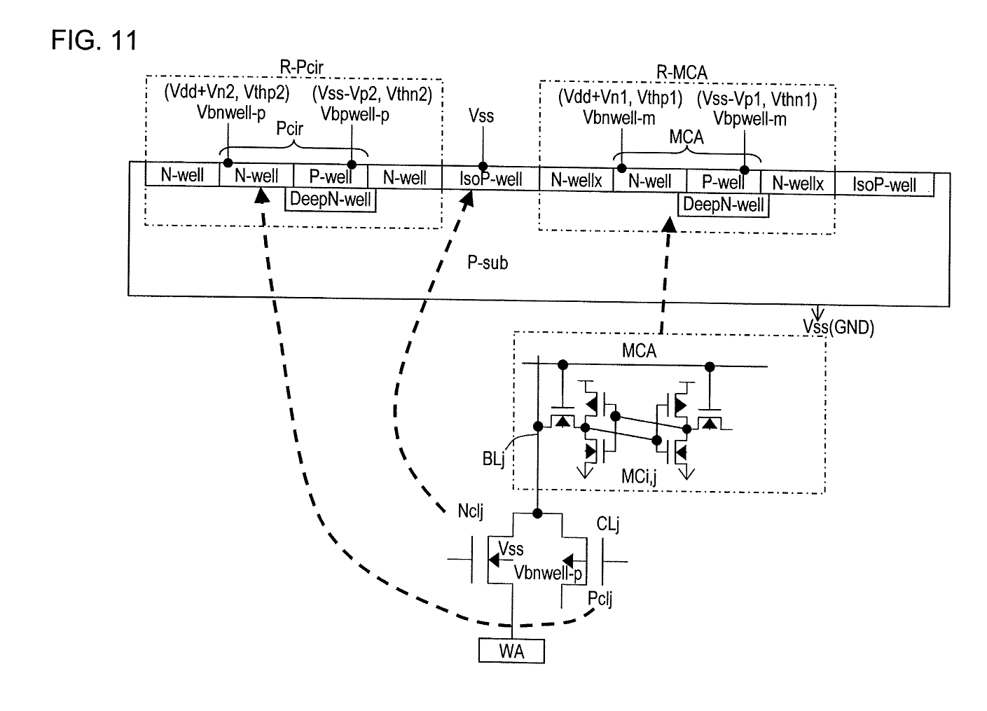

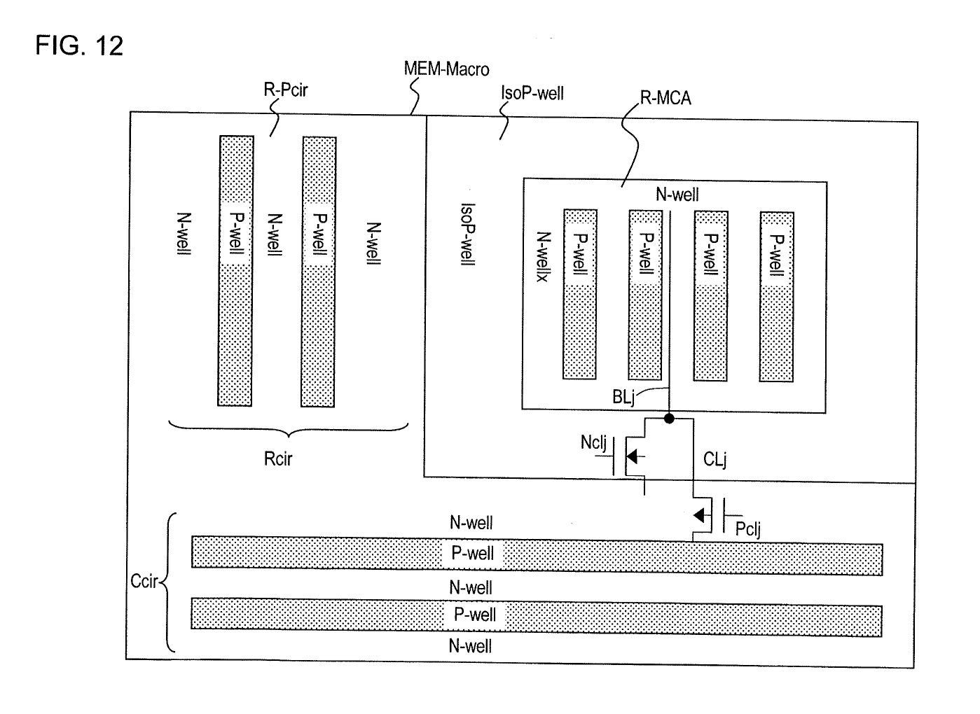

FIG. 11 is a cross-sectional view of the semiconductor memory device in a second embodiment. FIG. 12 is a plane view of the semiconductor memory device in the second embodiment. In the second embodiment, the NMOS transistors Nclj in the column selection circuits CLj of the column-side peripheral circuit Ccir that is the peripheral circuit Pcir are provided within a P-type well region for isolation IsoP-well. Further, the PMOS transistors Pclj in the column selection circuits CLj are provided within N-type well regions N-well in a peripheral circuit region R-Pcir. The PMOS transistors and NMOS transistors of the memory cell array are, similarly to the first embodiment, respectively provided in an N-type well region N-well and P-type well regions P-well within a memory cell array region R-MCA.

First, operation of the PMOS transistors Pclj and NMOS transistors Nclj in the column selection circuits CLi is explained. In FIG. 2, in a standby operation state other than a write operation or a readout operation, for example the NMOS transistors Nclj, Nclxj in the column selection circuits CLj are put into the non-conducting state. Further, bit line pairs BLj, BLxj are put at H level of the power supply voltage Vdd by conduction of the equalizing transistors Peq, Peqx. If the write amplifier WA operates so as to maintain the data bus line pair for writing WDb, WDBx at the same H level as the bit line pairs, there is little problem of off-leakage currents in the NMOS transistors Nclj, Nclxj. That is, the sources and drains of the NMOS transistors Nclj, Nclxj are at the same potential, so that off-leakage currents do not flow.

In FIG. 2, in a write operation the equalizing transistors Peq, Peqx are conducting, and consequently the bit line pairs BLj, BLxj, BLj+1, BLxj+1 are precharged to H level; in this state, a selected word line WL is driven to H level, and for example the NMOS transistors Nclj, Nclxj in the column selection circuit CLj are made conducting and the bit line pair BLj, BLxj is selected, and the write amplifier WA lowers one among the data bus line pair for writing WDB, WDBx, for example the data bus line WDB, to L level. At this time, the NMOS transistors Nclj+1, Nclxj+1 in the unselected-side column selection circuit CLj+1 are in the non-conducting state. There are concerns that, of the NMOS transistors Nclj+1, Nclxj+1 in this non-conducting state, a leakage current may occur in the NMOS transistor Nclj+1 on the side of the write data bus line WDB due to driving to L level of the write data bus line WDB, so that the potential of the unselected bit line BLj+1 drops, and erroneous writing to the memory cell in the half-selected state connected to the selected word line occurs. However, the equalizing transistor Peq is in the conducting state, the drop in potential of the unselected bit line BLj+1 is limited, and erroneous writing does not occur. Moreover, the write operation state persists for a short time, and the amount of the leakage current due to the NMOS transistor Nclj+1 is not very great.

Of the NMOS transistors Nclj+1, Nclxj+1 in the non-conducting state, an off-leakage current does not occur in the NMOS transistor Nclxj+1 on the side of the other write data bus line WDBx because the data bus line WDBx and the unselected bit line BLxj+1 are both at H level.

In FIG. 2, in a readout operation the equalizing transistors Peq, Peqx are conducting, and consequently the bit line pairs BLj, BLxj, BLj+1, BLxj+1 are precharged to H level; in this state, a selected word line WL is driven to H level, and for example the PMOS transistors Pclj, Pclxj in the column selection circuit CLj are made conducting and the bit line pair BLj, BLxj is selected. The potential of one among the bit line pair BLj, BLxj, for example the potential of the bit line BLj, is lowered by the memory cell, the lowering of the potential is transmitted to the readout data bus line RDB, and the sense amplifier SA detects this lowering of the potential. The potential on the bit line BLxj and readout data bus line RDBx remains at H level.

In this readout operation state, the NMOS transistors Nclj, Nclxj in the column selection circuit CLj of the selected column and the NMOS transistors Nclj+1, Nclxj+1 in the column selection circuit CLj+1 of the unselected column are transistors for writing, and so are in the non-conducting state. There are concerns that erroneous writing may occur due to leakage currents in this non-conducting state. However, the PMOS transistors Pclj+1, Pclxj+1 in the column selection circuit CLj+1 of the unselected column are also non-conducting, and so there is little effect due to leakage currents therein.

In a standby operation state other than a readout operation or write operation, a write operation state, and a readout operation state, off-leakage currents in the NMOS transistors in the column selection circuit do not pose a serious problem, and so by disposing the NMOS transistors Nclj, Nclxj, Nclj+1, Nclxj+1 of the column selection circuits within the P-type well region for isolation IsoP-well, area efficiency is improved. The PMOS transistors of the column selection circuits are disposed in N-type well regions N-well in the peripheral circuit region R-Pcir.

In this way, leakage currents do not occur in NMOS transistors in column selection circuits, for which the source and drain are at the same potential in operation states other than readout operations and write operations, and so there is no difficulty in disposing these transistors in the P-type well region for isolation IsoP-well, with the threshold voltage Vthn3 lower than Vthn2. Further, in readout operations and write operations, even should leakage currents occur in an unselected state, erroneous operation in the readout operation or write operation does not result.

NMOS transistors in peripheral circuits other than those above, which as transfer gates are NMOS transistors for which the source and drain are at the same potential in operation states other than readout operations and write operations, is also disposed in the P-type well region for isolation IsoP-well to improve area efficiency.

### Third Embodiment

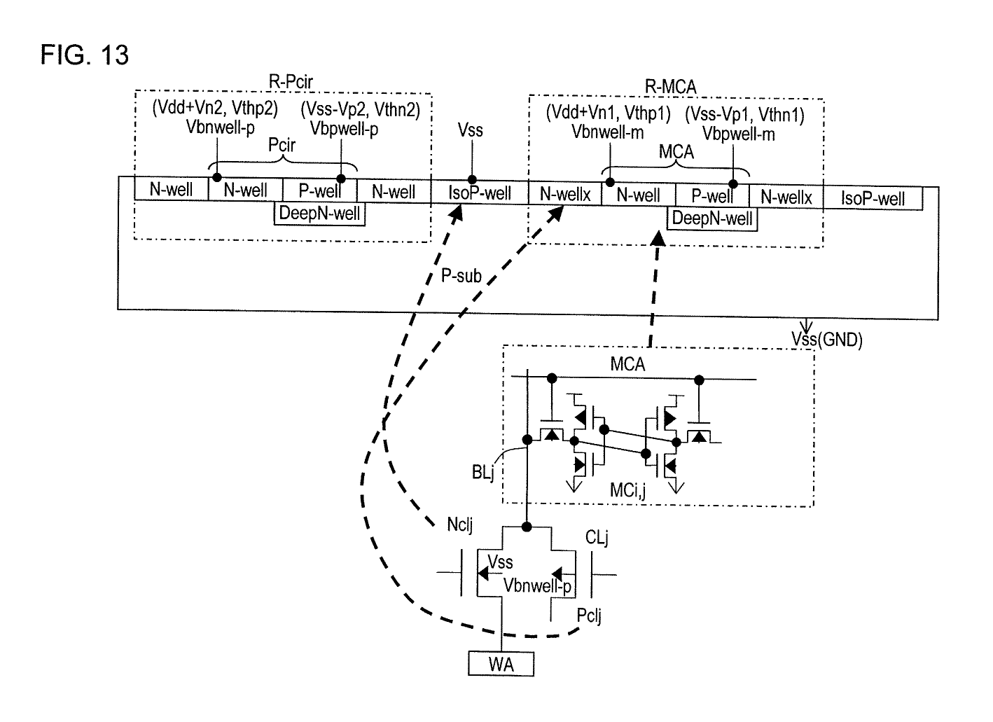

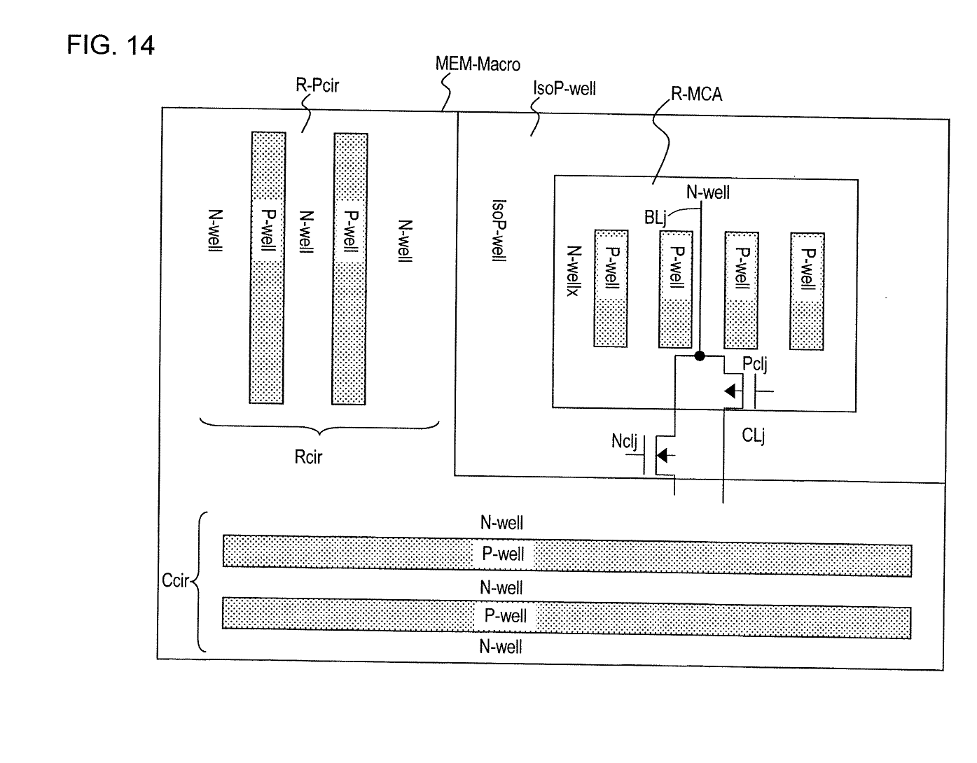

FIG. 13 is a cross-sectional view of the semiconductor memory device in a third embodiment. FIG. 14 is a plane view of the semiconductor memory device in the third embodiment. In the third embodiment, PMOS transistors Pclj in column selection circuits aj which are peripheral circuits Pcir are provided within a peripheral region N-wellx of an N-type well region N-well in a memory cell array region R-MCA. The NMOS transistors Nclj in the column selection circuits CLj of the column-side peripheral circuit may be provided in a P-type well region for isolation IsoP-well, as in the second embodiment, or may be provided in a P-type well region in a peripheral circuit region. Further, the PMOS transistors and NMOS transistors of the memory cell array are, similarly to the first and second embodiments, provided in an N-type well region N-well and in a P-type well region P-well respectively, within a memory cell array region R-MCA.

During a readout operation, the PMOS transistor Pclj in a column selection circuit CLj is conducting if the bit line pair BLj, BLxj is selected, and transmits a lowering of a bit line potential to the sense amplifier. Hence ordinarily, it is desirable that the PMOS transistor Pclj be provided in an N-type well region controlled at a standard threshold voltage Vthp2 in the peripheral circuit region R-Pcir and endowed with fast characteristics.

However, by providing the PMOS transistor Pclj in the column selection circuit in the N-type well region N-wellx controlled at a threshold voltage Vthp1 with a high absolute value within the memory cell array region R-MCA, even though fast characteristics are suppressed and current driving ability is reduced, the NMOS transistors N2, N4 (FIG. 1) in a memory cell MC have low current driving ability in a readout operation, and so there is not so great an effect on the speed of the drop in potential of the bit lines BL, BLx and readout data bus lines RDB, RDBx due to current draw of the NMOS transistors in the memory cell MC.

Hence by providing the PMOS transistor Pclj of the column selection circuit CLj in the peripheral region N-wellx of the N-type well region N-well within the memory cell array region R-MCA, area efficiency is improved.

As explained above, according to this embodiment, by disposing NMOS transistors of word driver circuits WD and NMOS transistors of column selection circuits CL in an isolation P-type well region IsoP-well which isolates an N-type well region of the memory cell array region (N-type memory cell array well region) and an N-type well region of the peripheral circuit region (N-type peripheral circuit well region), area efficiency is improved.

Further, by disposing PMOS transistors of column selection circuits CL in an N-type well region N-wellx in the vicinity surrounding a plurality of P-type well regions in an N-type memory cell array well region N-well, area efficiency is improved.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor memory device, comprising:
a memory cell array in which are disposed a plurality of memory cells, each including a first conduction type transistor and a second conduction type transistor;
a peripheral circuit which includes the first conduction type transistor and the second conduction type transistor, and which controls access to memory cells in the memory cell array;
a first conduction type memory cell array well region, which is within the region of the memory cell array, and in which are formed the second conduction type transistors of the plurality of memory cells;
a second conduction type memory cell array well region, which is within the first conduction type memory cell array well region, and in which are formed the first conduction type transistors of the plurality of memory cells;
a first conduction type peripheral circuit well region, which is within the region of the peripheral circuit, and in which is formed the second conduction type transistor of the peripheral circuit;
a second conduction type peripheral circuit well region, which is within the first conduction type peripheral circuit well region, and in which is formed the first conduction type transistor of the peripheral circuit; and
a second conduction type isolation region, which is disposed between the first conduction type memory cell array well region and the first conduction type peripheral circuit well region, wherein
at least a portion of first conduction type transistors of first conduction type transistors of the peripheral circuit is formed in the second conduction type isolation region.

2. The semiconductor memory device according to claim 1, wherein at least one of the portion of first conduction type transistors formed in the second conduction type isolation region includes a first conduction type transistor, which is conductive in an operation state other than a readout operation or a write operation.

3. The semiconductor memory device according to claim 2, wherein
the memory cell array includes a plurality of word lines connected to the plurality of memory cells,
the peripheral circuit includes a word driving circuit which is an inverter including the first conduction type transistor and the second conduction type transistor and which drives a selected word line, and
the first conduction type transistor which is conductive in an operation state other than a readout operation or a write operation includes the first conduction type transistor within the word driving circuit.

4. The semiconductor memory device according to claim 1, wherein at least one of the portion of first conduction type transistors formed in the second conduction type isolation region includes a first conduction type transistor, the source and drain of which are at the same potential in an operation state other than a readout operation or a write operation.

5. The semiconductor memory device according to claim 4, wherein
the memory cell array includes a plurality of bit lines connected to a plurality of memory cells,
the peripheral circuit includes a column selection circuit including a first conduction type transistor which connects at least one selected bit line among the plurality of bit lines to a data bus line, and
the first conduction type transistor, the source and drain of which are at the same potential in an operation state other than a readout operation or a write operation, includes a first conduction type transistor within the column selection circuit.

6. The semiconductor memory device according to claim 4, wherein the column selection circuit includes a transfer gate circuit between the bit line and a data bus line, and the first conduction type transistor, the source and drain of which are at the same potential in an operation state other than a readout operation or a write operation, includes a first conduction type transistor within the transfer gate circuit.

7. A semiconductor memory device, comprising:
a memory cell array in which are disposed a plurality of memory cells, each including a first conduction type transistor and a second conduction type transistor;
a peripheral circuit, which includes the first conduction type transistor and the second conduction type transistor, and which controls access to memory cells in the memory cell array;
a first conduction type memory cell array well region, which is within the region of the memory cell array, and in which are formed the second conduction type transistors of the plurality of memory cells;
a second conduction type memory cell array well region, which is within the first conduction type memory cell array well region, and in which are formed a first conduction type transistors of the plurality of memory cells;
a first conduction type peripheral circuit well region, which is within the region of the peripheral circuit, and in which is formed the second conduction type transistor of the peripheral circuit;
a second conduction type peripheral circuit well region, which is within the first conduction type peripheral circuit well region, and in which is formed the first conduction type transistor of the peripheral circuit; and
a second conduction type isolation region, which is disposed between the first conduction type memory cell array well region and the first conduction type peripheral circuit well region, wherein
at least a portion of second conduction type transistors of second conduction type transistors of the peripheral circuit is formed in a peripheral region of the first conduction type memory cell array well region surrounding the plurality of second conduction type memory cell array well regions in the region of the memory cell array.

8. The semiconductor memory device according to claim 7, wherein
the memory cell array includes a plurality of bit lines connected to a plurality of memory cells,
the peripheral circuit includes a column selection circuit including a second conduction type transistor which connects at least one selected bit line among the plurality of bit lines to a first data bus line, and
the portion of second conduction type transistors formed in the peripheral region of the first conduction type memory cell array well region includes the second conduction type transistor in the column selection circuit.

9. The semiconductor memory device according to claim 8, wherein the column selection circuit includes, in addition to the second conduction type transistor which connects a selected bit line to a first data bus line, a first conduction type transistor which connects the selected bit line to a second data bus line.

10. The semiconductor memory device according to claim 9, wherein the first conduction type transistor in the column selection circuit is formed in the second conduction type isolation region.

11. The semiconductor memory device according to claim 1, wherein different back gate voltages are supplied to the first conduction type memory cell array well region and to the first conduction type peripheral circuit well region.

12. The semiconductor memory device according to claim 11, wherein a first back gate voltage is supplied to the first conduction type memory cell array well region, and a second back gate voltage at positive potential lower than the first back gate voltage, is supplied to the first conduction type peripheral circuit well region.

13. The semiconductor memory device according to claim 1, wherein different back gate voltages are supplied to the second conduction type memory cell array well region and to the second conduction type peripheral circuit well region.

14. The semiconductor memory device according to claim 13, wherein a third back gate voltage is supplied to the second conduction type memory cell array well region, and a fourth back gate voltage at negative potential less negative than the third back gate voltage, is supplied to the second conduction type peripheral circuit well region.

15. The semiconductor memory device according to claim 14, wherein a fifth back gate voltage at potential less negative than the fourth back gate voltage is supplied to the second conduction type isolation region.

16. The semiconductor memory device according to claim 7, wherein different back gate voltages are supplied to the first conduction type memory cell array well region and to the first conduction type peripheral circuit well region.

17. The semiconductor memory device according to claim 16, wherein a first back gate voltage is supplied to the first conduction type memory cell array well region, and a second back gate voltage at positive potential lower than the first back gate voltage, is supplied to the first conduction type peripheral circuit well region.

18. The semiconductor memory device according to claim 7, wherein different back gate voltages are supplied to the second conduction type memory cell array well region and to the second conduction type peripheral circuit well region.

19. The semiconductor memory device according to claim 18, wherein a third back gate voltage is supplied to the second conduction type memory cell array well region, and a fourth back gate voltage at negative potential less negative than the third back gate voltage, is supplied to the second conduction type peripheral circuit well region.

20. The semiconductor memory device according to claim 19, wherein a fifth back gate voltage at potential less negative than the fourth back gate voltage is supplied to the second conduction type isolation region.
